(19) United States
(12) Patent Application Publication
(10) Pub. No.: US 2026/0313868 A1
(43) Pub. Date: Oct. 8, 2026

(54) MANUFACTURING METHOD OF A CAPACITOR-LESS MEMORY DEVICE

(71) Applicant: POSTECH RESEARCH AND BUSINESS DEVELOPMENT FOUNDATION, Pohang-si (KR)

(72) Inventors: Dae Hwan KANG, Pohang-si (KR); Yong Woo RYU, Pohang-si (KR); Gyu Heon BAE, Pohang-si (KR)

(21) Appl. No.: 19/639,656

(22) Filed: Apr. 6, 2026

(30) Foreign Application Priority Data
Apr. 8, 2025 (KR) 10-2025-0045755
Oct. 30, 2025 (KR) 10-2025-0160637

(51) Int. Cl. H10B 12/00

(52) U.S. Cl. CPC H10B 12/00

(57) ABSTRACT

A manufacturing method of a capacitor-less memory device includes stacking a plurality of first semiconductor layers on a substrate to be spaced apart from each other, forming a plurality of first gate electrode layers, forming a plurality of first gate insulating layers, forming at least one pair of first trenches, forming a plurality of back gate electrode layers, forming a plurality of first drain electrode layers, forming a plurality of first source electrode layers and a plurality of second gate electrode layers, forming a plurality of second semiconductor layers, forming a plurality of second gate insulating layers, forming a bit line, forming a plurality of word lines, and forming a plurality of control lines.

### CROSS-REFERENCE TO RELATED PATENT APPLICATION

This application claims the benefit under 35 U.S.C. § 119 of Korean Patent Application Nos. 10-2025-0045755 filed on April 8, 2025, and 10-2025-0160637 filed on October 30, 2025, the disclosures of which are hereby incorporated by reference in their entireties.

### BACKGROUND OF THE INVENTION

### 1. Field of the Invention

The present invention relates to a semiconductor device, and more particularly, to a memory device capable of data storage without a capacitor and a manufacturing method thereof.

This work was supported by the Ministry of Trade, Industry and Energy (MOTIE) and the Korea Evaluation Institute of Industrial Technology (KEIT) under the Public-Private Joint Investment Semiconductor Advanced Manpower Development Program (Project Unique Number: 2410000277, Project Number: 00235402).

### 2. Description of Related Arts

In general, memory devices can be classified into volatile devices, in which data is lost when power is turned off, and non-volatile devices, which retain data even when power is turned off. Among volatile devices, DRAM devices typically store data using a capacitor, and research is being conducted to increase data capacity by enlarging the capacitance of the capacitor.

A conventional DRAM device constitutes a memory cell with one transistor and one capacitor (1T-1C). However, in DRAM devices, as the volume of the capacitor increases, there is a limit to improving integration density, and manufacturing difficulty is also significantly increasing. Accordingly, research is being conducted on capacitor-less DRAM, which can perform the operations of a conventional DRAM device without a capacitor.

Conventionally, capacitor-less DRAM devices implement memory operations using two transistors and no capacitor (2T-0C). However, when implementing a device in a planar type, a wide cell area is still required, and the process of three-dimensional stacking to improve integration density is also challenging. In addition, when implementing a device in a vertical type, there is an advantage in that the area can be reduced; however, the process of three-dimensional stacking to improve integration density is likewise challenging.

### SUMMARY OF THE INVENTION

The present invention is directed to solving various problems including those described above, and an object of the present invention is to provide a capacitor-less memory device capable of high integration and having an easy stacking process, and a manufacturing method thereof. However, such objects are exemplary, and the scope of the present invention is not limited thereby.

In accordance with one aspect of the present invention for achieving the above object, a manufacturing method of a capacitor-less memory device may include: forming a plurality of first semiconductor layers stacked on a substrate so as to be spaced apart from each other, a plurality of first gate electrode layers disposed between the plurality of first semiconductor layers, and a plurality of first gate insulating layers disposed between the plurality of first semiconductor layers and the plurality of first gate electrode layers; patterning the plurality of first semiconductor layers, the plurality of first gate electrode layers, and the plurality of first gate insulating layers to form at least one pair of first trenches; removing the first semiconductor layers between the pair of first trenches, and forming a plurality of back gate electrode layers insulated from the plurality of first gate electrode layers in portions from which the first semiconductor layers have been removed; forming a plurality of first drain electrode layers connected respectively to one side of the plurality of first semiconductor layers; forming a plurality of first source electrode layers and a plurality of second gate electrode layers connected respectively to the other side of the plurality of first semiconductor layers; forming a plurality of second semiconductor layers extending vertically between the plurality of second gate electrode layers and the plurality of back gate electrode layers; forming a bit line connected to the plurality of first drain electrode layers and connected to an upper end of the second semiconductor layer; forming a plurality of word lines connected respectively to the plurality of first gate electrode layers; and forming a plurality of control lines connected respectively to the plurality of back gate electrode layers.

In the manufacturing method of the capacitor-less memory device, the method may further include, before the step of forming the pair of first trenches, forming a capping insulating layer on a stacked structure of the plurality of first semiconductor layers, the plurality of first gate insulating layers, and the plurality of first gate electrode layers, wherein in the step of forming the pair of first trenches, the capping insulating layer is also patterned together when patterning the stacked structure.

In the manufacturing method of the capacitor-less memory device, the method may further include, after the step of forming the pair of first trenches, selectively forming a first sidewall barrier layer on outer sidewalls of the pair of first trenches, wherein the first sidewall barrier layer protects the first semiconductor layers outside the pair of first trenches when removing the first semiconductor layers between the pair of first trenches.

In the manufacturing method of the capacitor-less memory device, the step of forming the first sidewall barrier layer may include: forming the first sidewall barrier layer entirely over the capping insulating layer and on inner surfaces of the first trenches; performing anisotropic etching to selectively remove the first sidewall barrier layer on bottoms of the first trenches and on the capping insulating layer; and selectively removing the first sidewall barrier layer on inner sidewalls of the pair of first trenches.

In the manufacturing method of the capacitor-less memory device, the step of forming the plurality of back gate electrode layers may include: using the first sidewall barrier layer as an etch protection layer, removing the first semiconductor layers between the pair of first trenches to form horizontal tunnels communicating with the pair of first trenches; forming a tunnel insulating layer on inner surfaces of the horizontal tunnels; forming a conductive material on the tunnel insulating layer to fill interiors of the horizontal tunnels; and selectively removing the conductive material remaining inside the pair of first trenches, except for the interiors of the horizontal tunnels.

In the manufacturing method of the capacitor-less memory device, after the step of forming the plurality of back gate electrode layers, the method may further include: removing the tunnel insulating layer remaining inside and outside the pair of first trenches; and forming a second sidewall barrier layer on inner sidewalls of the pair of first trenches that expose sidewalls of the plurality of back gate electrode layers.

In the manufacturing method of the capacitor-less memory device, using the second sidewall barrier layer as an etch protection layer, patterning the stacked structure outside the pair of first trenches from both sides in a direction perpendicular to the pair of first trenches toward the interior while leaving a central stacked line parallel to the pair of first trenches, to form a plurality of second trenches extending from the outside to the inside of the stacked structure by a predetermined distance in a direction perpendicular to the pair of first trenches; removing the first semiconductor layers within the central stacked line remaining between the plurality of second trenches; and forming a buried insulating layer filling the plurality of first trenches and the plurality of second trenches may further be included.

In the manufacturing method of the capacitor-less memory device, the step of forming the plurality of first drain electrode layers may include: forming a plurality of first vertical holes penetrating the buried insulating layer and the plurality of first semiconductor layers so as to expose one side of the plurality of first semiconductor layers; etching one side of the plurality of first semiconductor layers by a predetermined amount through the plurality of first vertical holes to form first lateral recesses; and filling a conductive material to fill the first lateral recesses so as to be connected respectively to one side of the plurality of first semiconductor layers.

In the manufacturing method of the capacitor-less memory device, the step of forming the plurality of first source electrode layers and the plurality of second gate electrode layers may include: forming a plurality of second vertical holes penetrating the buried insulating layer so as to expose the other side of the plurality of first semiconductor layers; etching the other side of the plurality of first semiconductor layers by a predetermined amount through the plurality of second vertical holes to form second lateral recesses; and filling a conductive material to fill the second lateral recesses so as to be connected respectively to the other side of the plurality of first semiconductor layers, thereby simultaneously forming the plurality of first source electrode layers and the plurality of second gate electrode layers.

In the manufacturing method of the capacitor-less memory device, the method may further include forming a plurality of second gate insulating layers between the plurality of second gate electrode layers and the plurality of second semiconductor layers and between the plurality of back gate electrode layers and the plurality of second semiconductor layers, wherein the step of forming the plurality of second gate insulating layers and the step of forming the plurality of second semiconductor layers may include: forming the plurality of second gate insulating layers on inner surfaces of the plurality of second vertical holes; and forming the plurality of second semiconductor layers on the plurality of second gate insulating layers to fill the plurality of second vertical holes.

In the manufacturing method of the capacitor-less memory device, the step of forming the bit line may include: forming a plurality of first vertical via electrodes extending vertically by filling the plurality of first vertical holes so as to be connected to the plurality of first drain electrode layers; and forming a plurality of first horizontal electrodes extending horizontally so as to be connected to upper ends of the plurality of second semiconductor layers and connected to the plurality of first vertical via electrodes.

In the manufacturing method of the capacitor-less memory device, the plurality of first vertical via electrodes and the plurality of first drain electrode layers may be formed simultaneously.

In the manufacturing method of the capacitor-less memory device, the step of forming the plurality of word lines may include: step-wise etching end portions of the plurality of first gate electrode layers to expose the plurality of first gate electrode layers; forming second vertical via electrodes on the step-wise exposed portions of the plurality of first gate electrode layers; and forming second horizontal electrodes extending in a horizontal direction and connected respectively to the second vertical via electrodes.

In the manufacturing method of the capacitor-less memory device, the step of forming the plurality of control lines may include: step-wise etching end portions of the plurality of back gate electrode layers to expose the plurality of back gate electrode layers; forming third vertical via electrodes on the step-wise exposed portions of the plurality of back gate electrode layers; and forming third horizontal electrodes extending in a horizontal direction and connected respectively to the third vertical via electrodes.

In the manufacturing method of the capacitor-less memory device, the method may further include, before stacking the plurality of first semiconductor layers, forming an interlayer insulating layer on the substrate; and forming a plurality of via electrodes extending vertically within the interlayer insulating layer, wherein the plurality of first semiconductor layers may be stacked on the interlayer insulating layer.

In the manufacturing method of the capacitor-less memory device, the method may further include, before the step of forming the interlayer insulating layer, forming a device isolation layer within the substrate to define select lines within the substrate, wherein the plurality of via electrodes are formed so as to be connected respectively to the select lines, the plurality of via electrodes connect a portion of the plurality of second semiconductor layers and the select lines, and connect the plurality of bit lines and another portion of the select lines.

In the manufacturing method of the capacitor-less memory device, each of the plurality of first semiconductor layers may have a planar shape, and the plurality of second semiconductor layers may have a pillar shape.

In the manufacturing method of the capacitor-less memory device, the plurality of first semiconductor layers and the plurality of second semiconductor layers may include an oxide semiconductor.

In accordance with another aspect of the present invention for achieving the above object, a manufacturing method of a capacitor-less memory device may include: stacking a plurality of first semiconductor layers on a substrate so as to be spaced apart from each other; forming a plurality of first gate electrode layers disposed between the plurality of first semiconductor layers; forming a plurality of first gate insulating layers disposed between the plurality of first semiconductor layers and the plurality of first gate electrode layers; patterning the plurality of first semiconductor layers, the plurality of first gate electrode layers, and the plurality of first gate insulating layers to form at least one pair of first trenches; removing the first semiconductor layers between the pair of first trenches, and forming a plurality of back gate electrode layers insulated from the plurality of first gate electrode layers in portions from which the first semiconductor layers have been removed; removing one side of the plurality of first semiconductor layers by a predetermined amount, and then filling a conductive material in the removed portions to form a plurality of first drain electrode layers connected respectively to one side of the plurality of first semiconductor layers; removing the other side of the plurality of first semiconductor layers by a predetermined amount, and then filling a conductive material in the removed portions to form a plurality of first source electrode layers and a plurality of second gate electrode layers connected respectively to the other side of the plurality of first semiconductor layers; forming a plurality of second semiconductor layers extending vertically between the plurality of second gate electrode layers and the plurality of back gate electrode layers; forming a plurality of second gate insulating layers between the plurality of second gate electrode layers and the plurality of second semiconductor layers and between the plurality of back gate electrode layers and the plurality of second semiconductor layers; forming a bit line connected to the plurality of first drain electrode layers and connected to an upper end of the second semiconductor layer; forming a plurality of word lines connected respectively to the plurality of first gate electrode layers; and forming a plurality of control lines connected respectively to the plurality of back gate electrode layers.

According to the capacitor-less memory device in accordance with some embodiments of the present invention as described above, a memory cell having two transistors, namely a write transistor and a read transistor, without a capacitor is employed, wherein a bit line is commonly connected to both drains and a back gate structure is utilized to reduce the area of the memory cell, thereby enabling an increase in integration density, and the integration density can be further increased through three-dimensional stacking. Of course, the scope of the present invention is not limited by these effects.

### BRIEF DESCRIPTION OF THE DRAWINGS

FIG. 1 is a schematic circuit diagram showing a capacitor-less memory device according to an embodiment of the present invention.

FIG. 2 is a time chart exemplarily showing an operation of the capacitor-less memory device of FIG. 1.

FIG. 3 is a schematic circuit diagram showing a capacitor-less memory device according to another embodiment of the present invention.

FIGS. 4 and 5 are schematic perspective views of a capacitor-less memory device according to still another embodiment of the present invention, as viewed from the front and the back, respectively.

FIGS. 6 through 26 are schematic diagrams showing a manufacturing method of a capacitor-less memory device according to still another embodiment of the present invention.

### DETAILED DESCRIPTION OF THE INVENTION

Hereinafter, various preferred embodiments of the present invention will be described in detail with reference to the accompanying drawings.

The embodiments of the present invention are provided to more completely explain the present invention to those skilled in the art, and the following embodiments may be modified in various different forms, and the scope of the present invention is not limited to the following embodiments. Rather, these embodiments are provided to make the present disclosure more faithful and complete, and to fully convey the spirit of the present invention to those skilled in the art. In addition, the thickness or size of each layer in the drawings is exaggerated for convenience and clarity of description.

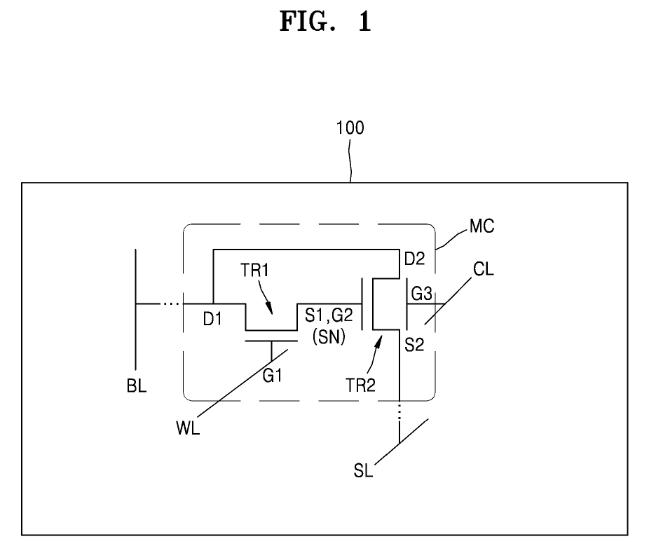

FIG. 1 is a schematic circuit diagram showing a capacitor-less memory device 100 according to an embodiment of the present invention.

Referring to FIG. 1, the capacitor-less memory device 100 may include a memory cell MC. The memory device 100 may process data using the memory cell MC, and the memory cell MC may store and read data without a capacitor. The memory device 100 may include a dynamic random-access memory (DRAM) device.

More specifically, the memory cell MC may include a write transistor TR1 and a read transistor TR2. The write transistor TR1 includes a first gate G1, a first drain D1, and a first source S1, and the read transistor TR2 may include a second gate G2, a second drain D2, a second source S2, and a back gate G3. For example, the write transistor TR1 and the read transistor TR2 may be provided as metal oxide field effect transistors (MOSFETs).

In the memory cell MC, the second gate G2 of the read transistor TR2 is connected to the first source S1 of the write transistor TR1 and may operate as a storage node SN. For example, the first source S1 and the second gate G2 may be separate but may be interpreted as being connected to each other. As another example, the first source S1 and the second gate G2 may be integrally formed without being separated from each other and may simultaneously perform the function of the first source S1 and the function of the second gate G2. In this case, the first source S1 and the second gate G2 may not be separately referred to, but may be collectively referred to as one of the two, or may be referred to as the storage node SN.

The bit line BL may be commonly connected to the first drain D1 of the write transistor TR1 and the second drain D2 of the read transistor TR2. Accordingly, the same operation signal may be applied to the first drain D1 and the second drain D2 through the bit line BL. Such a structure simplifies the structure of the memory cell MC, thereby reducing its area and simplifying its structure during stacking.

In some embodiments, a row select transistor (not shown) may be additionally provided between the bit line BL and the memory cell MC. For example, the row select transistor may be connected between the bit line BL and the first drain D1 of the write transistor TR1. The row select transistor STR1 may control the connection between the bit line BL and the memory cell MC when the memory cells MC are arranged in a plurality of rows.

Furthermore, the word line WL may be connected to the first gate G1 of the write transistor TR1. Through a control signal applied to the word line WL, the turn-on or turn-off state of the write transistor TR1 may be controlled. For example, when a write operation voltage is applied to the word line WL, the write transistor TR1 may be turned on, and when an off voltage is applied to the word line WL, the write transistor TR1 may be turned off.

In the memory cell MC, the second gate G2 of the read transistor TR2 is not connected to an external terminal and may receive an output signal of the first source S1 of the write transistor TR1. The read transistor TR2 may be controlled by the back gate G3. The control line CL is connected to the back gate G3, and through a control signal applied to the control line CL, the turn-on or turn-off state of the read transistor TR2 may be controlled. For example, when an operation voltage is applied to the control line CL, the read transistor TR2 may be turned on, and when an off voltage is applied to the control line CL, the read transistor TR2 may be turned off.

In some embodiments, the select line SL may be connected to the second source S2 of the read transistor TR2. For example, a separate electrical signal may be applied to the select line SL. As another example, when it is not necessary to apply a separate electrical signal through the select line SL, the select line SL may be omitted, and the second source S2 of the read transistor TR2 may be connected to a ground.

In some embodiments, a column select transistor (not shown) may be further connected between the second source S2 and the select line SL. Such a column select transistor may control the connection between the select line SL and the memory cell MC when the memory cells MC are arranged in a plurality of columns.

The memory cell MC may store a data state in the storage node SN and may read the data state of the storage node SN. For example, the read transistor TR2 may be turned on or turned off according to the data state of the storage node SN or a control voltage applied to the control line CL.

Hereinafter, the operation of the memory device 100 will be described in more detail.

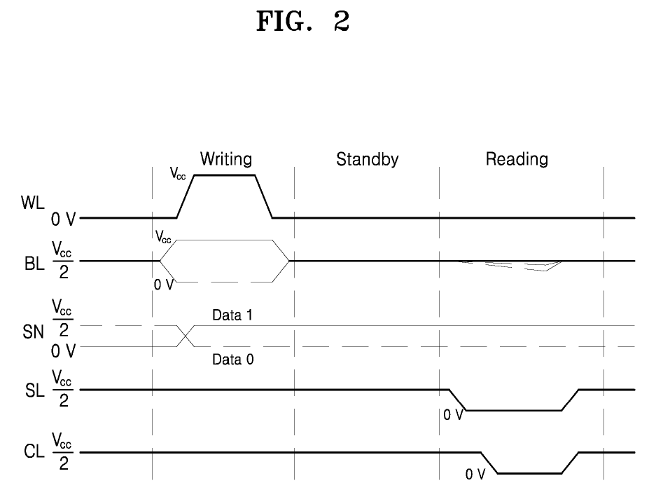

FIG. 2 is a timing chart illustrating an exemplary operation of the capacitor-less memory device 100 of FIG. 1.

Referring to FIGS. 1 and 2, a write operation of storing data in the storage node SN of the memory cell MC and a read operation of reading data stored in the storage node SN may be performed. The data stored in the storage node SN may include a first data state (Data 1) and a second data state (Data 0). For example, the first data state (Data 1) refers to a state in which a first data voltage (e.g., Vcc/2) is stored in the storage node SN, and the second data state (Data 0) may refer to a state in which a second data voltage (e.g., 0 V) is stored in the storage node SN. The first data voltage (Vcc/2) may be greater than the second data voltage (0 V), and accordingly the first data state (Data 1) is a relatively high level state and the second data state (Data 0) may refer to a relatively low level state.

More specifically, during a write operation of storing the first data state (Data 1) in the storage node SN of the memory cell MC, a write operation voltage (e.g., Vcc) may be applied to the word line WL and the bit line BL. Additionally, a precharge voltage (e.g., Vcc/2) or an off voltage (e.g., 0 V) may be applied to the control line CL.

Hereinafter, the write operation voltage (Vcc) may be selected as a voltage greater than the precharge voltage (Vcc/2), for example, twice the precharge voltage (Vcc/2), in order to store a voltage greater than the threshold voltage of the read transistor TR2 as the precharge voltage (Vcc/2) in the storage node SN. The off voltage (0 V) may be a voltage lower than the threshold voltage of the write transistor TR1 and the threshold voltage of the read transistor TR2, for example, 0 V, in order to turn off the write transistor TR1 or the read transistor TR2.

In some embodiments, during the write operation of the first data state (Data 1), a precharge voltage (e.g., Vcc/2) or a write operation voltage (Vcc) may be applied to the select line SL.

In some embodiments, during the write operation of the first data state (Data 1), the voltage of the bit line BL may be raised from the precharge voltage (e.g., Vcc/2) to the write operation voltage (Vcc). Accordingly, as the write transistor TR1 is turned on, the voltage of the storage node SN may be raised to the first data voltage (Vcc/2). Such a write operation of the first data may also be referred to as a data storage operation.

During a write operation of storing the second data state (Data 0) in the storage node SN of the memory cell MC, the write operation voltage (Vcc) may be applied to the word line WL, the off voltage (0 V) may be applied to the bit line BL, and the precharge voltage (Vcc/2) or the off voltage (0 V) may be applied to the control line CL. Accordingly, as the write transistor TR1 is turned on, the voltage of the storage node SN may be lowered to the second data voltage (0 V). Such a write operation of the second data state may also be referred to as a data erase operation.

In some embodiments, during the write operation of the second data state (Data 0), a precharge voltage (e.g., Vcc/2) or an off voltage (0 V) may be applied to the select line SL.

In a standby operation, the off voltage (0 V) may be applied to the word line WL, and the precharge voltage (Vcc/2) may be applied to the bit line BL, the control line CL, and the select lines SL. In this case, as the write transistor TR1 is turned off, the data state of the storage node SN may be maintained. For example, the voltage of the storage node SN may be maintained at the first data state (Vcc/2) or the second data state (e.g., 0 V).

In a read operation, the off voltage (0 V) may be applied to the word line WL, the off voltage (0 V) may be applied to the control line CL and the select line SL, and the voltage of the bit line BL may be read. For example, the data state may be read by sensing the degree of drop of the precharge voltage (Vcc/2) on the bit line BL. In this case, the write transistor TR1 is turned off, and the read transistor TR2 may be turned on or turned off according to the data state of the storage node SN. For example, the precharge voltage (Vcc/2) may be greater than the threshold voltage of the read transistor TR2. Accordingly, when the precharge voltage (Vcc/2) is stored in the storage node SN of the read transistor TR2, the read transistor TR2 may be turned on.

For example, when the storage node SN is in the first data state (Data 1), the read transistor TR2 is turned on and current flows through the read transistor TR2, so that the voltage of the bit line BL may drop by a predetermined amount from the precharge voltage (Vcc/2). As another example, when the storage node SN is in the second data state (Data 0), the read transistor TR2 is turned off so that the voltage of the bit line BL may be maintained substantially unchanged from the precharge voltage (Vcc/2).

However, since there is a slight leakage current in the read transistor TR2, the voltage of the bit line BL may drop slightly from the precharge voltage (Vcc/2) even in the second data state (Data 0). For example, during a read operation, the voltage of the bit line BL in the first data state (Data 1) may be greater than a reference voltage, and the voltage of the bit line BL in the second data state (Data 0) may be less than the reference voltage.

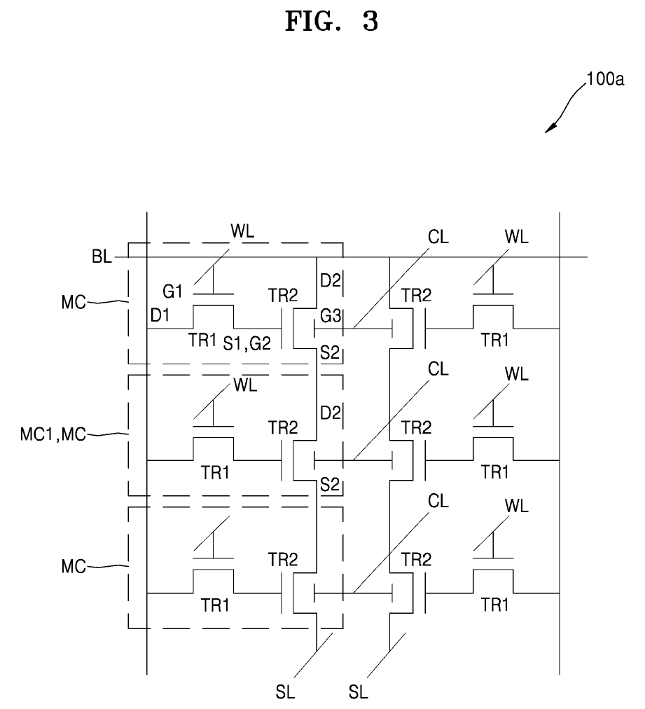

FIG. 3 is a schematic circuit diagram showing a capacitor-less memory device 100a according to another embodiment of the present invention. The memory device 100a may represent a case in which some configurations of the memory device 100 of FIG. 1 are modified or added, and therefore the two embodiments may be referenced with each other, and duplicate descriptions in the two embodiments are omitted.

Referring to FIGS. 1 and 3 together, the capacitor-less memory device 100a may include a plurality of memory cells MC. For example, the memory cells MC may be vertically stacked. Furthermore, the memory cells MC may be further arranged in a two-dimensional array form. Each memory cell MC may include a write transistor TR1 and a read transistor TR2, and reference may be made to the description of FIG. 1.

The memory cells MC may include a plurality of write transistors TR1 vertically stacked and a plurality of read transistors TR2 vertically connected to each other. For example, the write transistors TR1 may be vertically stacked in a single column, and the read transistors TR2 may be connected in series along a single vertical string. For example, in two vertically adjacent read transistors TR2, the second drain D2 and the second source S2 may be connected to each other.

The bit line BL may be connected to the first drain D1 of the memory cells MC. Furthermore, the bit line BL may be connected to the second drain D2 of the topmost read transistor TR2 among the read transistors TR2. A plurality of word lines WL may be respectively connected to the first gate G1 of the memory cells MC. A plurality of control lines CL may be respectively connected to the back gate G3 of the memory cells MC.

In some embodiments, the select line SL may be connected to the second source S2 of the bottommost read transistor TR2 among the read transistors TR2. Accordingly, the read transistors TR2 may be connected in series between the bit line BL and the select line SL. Accordingly, only when all of the read transistors TR2 in the vertically stacked memory cells MC are turned on, current may flow from the bit line BL to the select line SL through the read transistors TR2.

In some embodiments, in two memory cells MC adjacently arranged in the same row, the two back gates G3 may be connected to the same control line CL.

In the memory device 100a, the read transistor TR2 may be turned on or turned off according to the data state of the storage node SN or a control voltage applied to the back gate G3 through the control line CL.

In some embodiments, among the memory cells MC, a memory cell MC1 disposed in the second layer and first column may be exemplarily selected, and write and read operations may be performed.

For example, a write operation for storing the first data state (Data 1) in the storage node SN of the selected memory cell MC1 among the memory cells MC may be performed. More specifically, during a write operation of storing the first data state (Data 1) in the storage node SN of the selected memory cell MC1, the write operation voltage (Vcc) may be applied to the bit line BL, the write operation voltage (Vcc) may be applied to the word line WL connected to the selected memory cell MC1 among the word lines WL, the off voltage (0 V) may be applied to the remaining word lines WL, the off voltage (0 V) may be applied to the control line CL, and the precharge voltage (Vcc/2) may be applied to the select line SL. Such a write operation of the first data may also be referred to as a data storage operation.

For example, a read operation of reading the data state of the storage node SN of the selected memory cell MC1 among the memory cells MC may be performed. More specifically, in order to read the data state of the selected memory cell MC1 among the plurality of memory cells MC, the off voltage (0 V) may be applied to the word lines WL, the off voltage (0 V) may be applied to the control line CL connected to the back gate G3 of the selected memory cell MC1 among the control lines CL and the precharge voltage (Vcc/2) may be applied to the remaining control lines CL, the off voltage (0 V) may be applied to the select line SL, and the degree of voltage drop on the bit line BL, for example, the degree of drop of the precharge voltage (Vcc/2), may be sensed.

Accordingly, according to the memory device 100a, the memory cells MC may be arranged in a two-dimensional array, and furthermore may be vertically arranged in a three-dimensional manner, thereby increasing the integration density of the memory cells MC. Furthermore, through the common connection structure of the bit line BL, the structure may be simplified. Accordingly, the unit area of each memory cell MC may be reduced, and the stacked structure thereof may be simplified. Furthermore, by sharing the control line of adjacent memory cells MC, the overall integration density of the memory device 100a may be further increased.

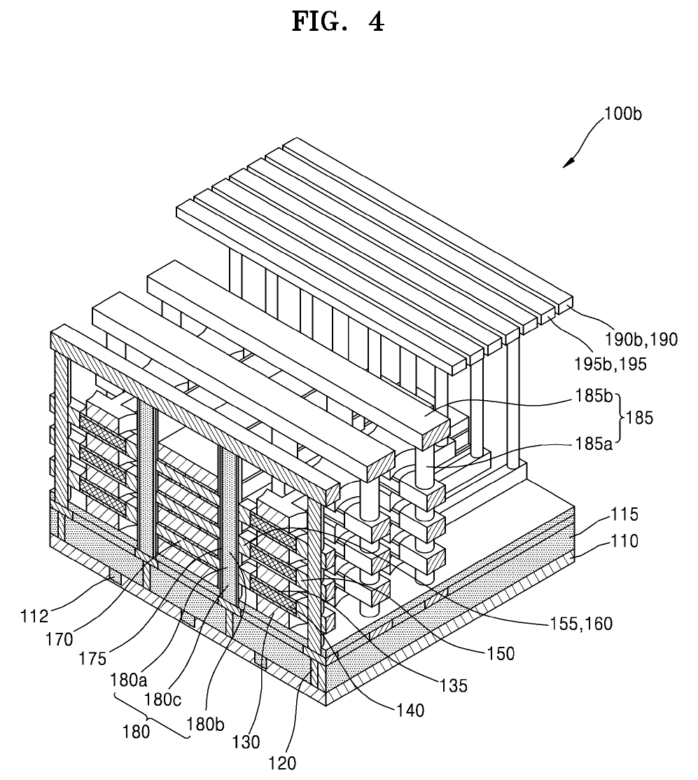

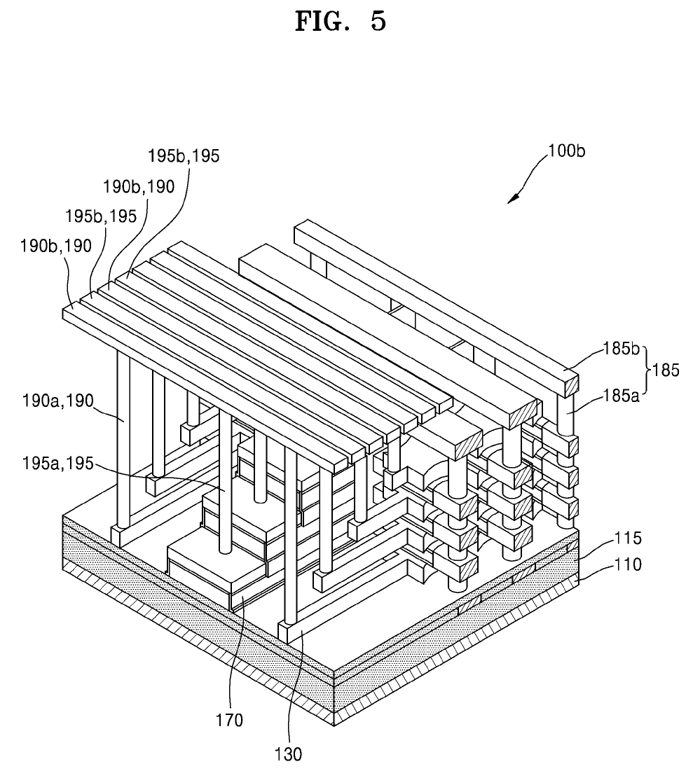

FIGS. 4 and 5 are schematic perspective views of a capacitor-less memory device 100b according to still another embodiment of the present invention, viewed from the front and rear, respectively.

Referring to FIGS. 4 and 5, the capacitor-less memory device 100b may include a plurality of first semiconductor layers 140, a plurality of first gate electrode layers 130, a plurality of second semiconductor layers 180, a plurality of second gate electrode layers 160, and a plurality of back gate electrode layers 170.

More specifically, a substrate 110 may be provided. For example, the substrate 110 may include a semiconductor wafer such as silicon, silicon carbide, gallium nitride, gallium oxide, germanium, or silicon-germanium. In some embodiments, the substrate 110 may include a semiconductor wafer and at least one epitaxial layer (not shown) grown thereon. For example, the substrate 110 may have a silicon-on-insulator (SOI) structure.

In some embodiments, a device isolation layer 112 may be formed in the substrate 110. Furthermore, at least one active device, for example, a transistor, may be formed in the substrate 110.

The plurality of first semiconductor layers 140 may be stacked on the substrate 110 so as to be spaced apart from each other. For example, an interlayer insulating layer 115 may be formed on the substrate 110, and the first semiconductor layers 140 may be stacked on the interlayer insulating layer 115 so as to be spaced apart from each other. For example, the first semiconductor layers 140 may include a semiconductor material such as silicon, zirconium, or an oxide semiconductor. For example, the first semiconductor layers 140 may include an oxide semiconductor such as indium gallium zinc oxide (IGZO). Each first semiconductor layer 140 may be formed in various shapes, and may have, for example, a wire or plate shape.

The plurality of first gate electrode layers 130 may be disposed between the first semiconductor layers 140. For example, a first gate electrode layer 130 may be disposed between each adjacent two of the first semiconductor layers 140. The first gate electrode layers 130 may be formed of a conductive material such as doped polysilicon or a metal.

A first gate insulating layer 135 may be provided between the first semiconductor layers 140 and the first gate electrode layers 130. For example, the first gate insulating layer 135 may be formed on the surface of the first semiconductor layers 140, and the first gate electrode layers 130 may be formed on the first gate insulating layer 135. For example, the first gate insulating layer 135 may be formed by depositing an insulating material on the first semiconductor layers 140.

A plurality of first drain electrode layers 150 are respectively connected to one side of the first semiconductor layers 140, and a plurality of first source electrode layers 155 may be respectively connected to the other side of the first semiconductor layers 140. For example, the first drain electrode layers 150 and the first source electrode layers 155 may include a conductive material such as a metal. As another example, the first drain electrode layers 150 and the first source electrode layers 155 may be portions of the first semiconductor layers 140 exposed from the first gate electrode layers 130 on both sides of the first gate electrode layers 130.

The combined structure of the first semiconductor layer 140, the first gate electrode layer 130, the first drain electrode layer 150, and the first source electrode layer 155 may constitute the write transistor TR1 in the memory cell MC of FIG. 1. For example, the first semiconductor layer 140, the first gate electrode layer 130, the first drain electrode layer 150, and the first source electrode layer 155 may correspond to the channel, the first gate G1, the first drain D1, and the first source S1 of the write transistor TR1 of FIG. 1, respectively.

Furthermore, the stacked structure of the first semiconductor layers 140, the first gate electrode layers 130, the first drain electrode layers 150, and the first source electrode layers 155 may correspond to the stacked structure of the write transistors TR1 in the memory device 100a of FIG. 3.

Meanwhile, the plurality of second gate electrode layers 160 may be respectively connected to the first source electrode layers 155. For example, the second gate electrode layers 160 may be formed of a conductive material such as doped polysilicon or a metal.

The second semiconductor layers 180 may extend vertically across the second gate electrode layers 160. For example, the second semiconductor layers 180 may include a semiconductor material such as silicon, germanium, or an oxide semiconductor. For example, the second semiconductor layers 180 may include an oxide semiconductor such as indium gallium zinc oxide (IGZO). The second semiconductor layers 180 may be formed in various shapes, and may have, for example, a vertical pillar shape.

The plurality of back gate electrode layers 170 may be respectively disposed on the opposite side of the second semiconductor layers 180 from the second gate electrode layers 160. For example, the second gate electrode layers 160 may be disposed on one side of the second semiconductor layers 180 so as to be vertically spaced apart, and the back gate electrode layers 170 may be disposed on the other side of the second semiconductor layers 180 so as to be vertically spaced apart. The back gate electrode layers 170 and the second gate electrode layers 160 may be disposed in the same layer with the second semiconductor layers 180 interposed therebetween, respectively.

A second gate insulating layer 175 may be provided between the second gate electrode layers 160 and the second semiconductor layers 180 and between the back gate electrode layers 170 and the second semiconductor layers 180. For example, the second gate insulating layer 175 may be formed by depositing an insulating material on the second semiconductor layers 180.

The combined structure of the second semiconductor layer 180, the second gate electrode layer 160, and the back gate electrode layer 170 may constitute the read transistor TR2 in the memory cell MC of FIG. 1. For example, the second semiconductor layer 180, the second gate electrode layer 160, and the back gate electrode layer 170 may correspond to the channel, the second gate G2, and the back gate G3 of the read transistor TR2 of FIG. 1, respectively.

Furthermore, the stacked structure of the second semiconductor layer 180, the second gate electrode layers 160, and the back gate electrode layers 170 may correspond to the stacked structure of the read transistors TR2 in the memory device 100a of FIG. 3.

In some embodiments, second drain electrode layers 180b and second source electrode layers 180c may be provided as portions of the second semiconductor layers 180. For example, in the second semiconductor layers 180, portions facing the second gate electrode layers 160 may function as channel layers 180a. The channel layers 180a may also be referred to as portions of the second semiconductor layers 180 between the second gate electrode layers 160 and the back gate electrode layers 170. Furthermore, portions of the second semiconductor layers 180 between the channel layers 180a may function as the second drain electrode layers 180b and the second source electrode layers 180c.

The second drain electrode layer 180b and the second source electrode layer 180c may correspond to the second drain D2 and the second source S2 of the read transistor TR2 of FIG. 1, respectively. Accordingly, in adjacent memory cells MC, the second drain electrode layer 180b and the second source electrode layer 180c may be connected to each other.

In some embodiments, the first source electrode layer 155 and the second gate electrode layer 160 disposed in the same layer among the first source electrode layers 155 and the second gate electrode layers 160 may be integrally formed with each other.

In some embodiments, a plurality of word lines 190 may be respectively connected to the first gate electrode layers 130, and a plurality of control lines 195 may be respectively connected to the back gate electrode layers 170. For example, the word lines 190 and the control lines 195 may be alternately arranged.

In some embodiments, a bit line 185 may be connected to the first drain electrode layers 150, and the second semiconductor layer 180 may be connected at the top end. More specifically, the bit line 185 may be commonly connected to the topmost second drain electrode layer 180b of the second semiconductor layer 180 and the vertically stacked first drain electrode layers 150.

For example, each bit line 185 may include a first vertical via electrode 185a extending vertically so as to be commonly connected to the vertically stacked first drain electrode layers 150, and a first horizontal electrode 185b extending horizontally so as to be connected to the top end of the second semiconductor layer 180. The first vertical via electrode 185a and the first horizontal electrode 185b may be connected to each other.

For example, each word line 190 may include a second vertical via electrode 190a connected to each first gate electrode layer 130, and a second horizontal electrode 190b connected to the second vertical via electrode 190a and extending horizontally.

For example, each control line 195 may include a third vertical via electrode 195a connected to each back gate electrode layer 170, and a third horizontal electrode 195b connected to the third vertical via electrode 195a and extending horizontally.

In some embodiments, the first semiconductor layers 140 may each have a planar shape, and the second semiconductor layer 180 may have a pillar shape. For example, the first semiconductor layers 140 may have a thin rectangular planar shape, and the second semiconductor layer 180 may have a circular cylindrical or elliptical cylindrical shape.

In some embodiments, via electrodes 120 formed in the interlayer insulating layer 115 may be provided. For example, the via electrodes 120 may connect the substrate 110 to the bottom end of the second semiconductor layer 180 or may connect the substrate 110 to the bit line 185.

In some embodiments, a select line (not shown) may be added on the substrate 110 so as to be connected to the bottom end of the second semiconductor layer 180, or a portion of the substrate 110 connected to the bottom end of the second semiconductor layer 180 may function as a select line. For example, the via electrodes 120 may connect portions of the second semiconductor layers 180 and the select lines, and may connect other portions of the bit lines 185 and the select line.

It will be understood that, in the capacitor-less memory device 100b described above, illustration of some insulating layers is omitted for convenience of illustration of the bit lines 185, the word lines 190, and the control lines 195.

According to the capacitor-less memory device 100b described above, by stacking the first semiconductor layers 140 and forming the second semiconductor layer 180 as a vertical pillar, memory cells (MC of FIG. 3) having a vertically stacked structure may be formed with high integration density. Furthermore, by forming the bit line 185 such that the first vertical via electrode 185a and the first horizontal electrode 185b are connected, the connection structure may be simplified. In addition, by sharing the back gate electrode layers 170 between adjacent second semiconductor layers 180, the integration density may be further increased.

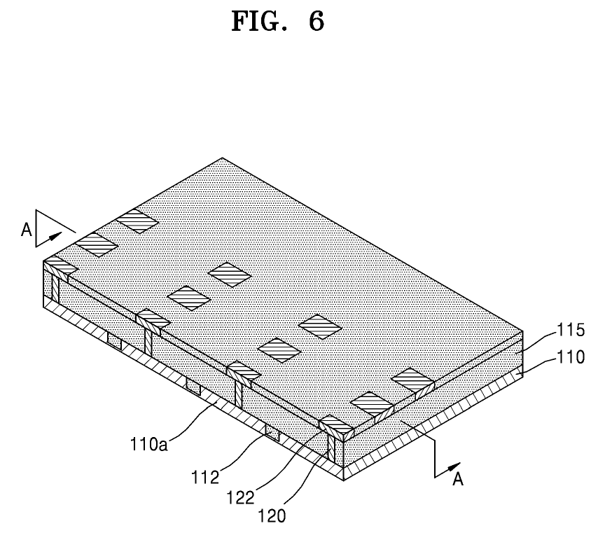

FIGS. 6 through 26 are schematic diagrams showing a manufacturing method of the capacitor-less memory device 100b according to still another embodiment of the present invention. FIGS. 6 through 26 may be composed of perspective views or cross-sections, and the cross-sections may be based on a cross-sectional view taken along line AA of FIG. 6.

Hereinafter, the manufacturing process may include a deposition or plating process for forming a material film, a photolithography process for forming a pattern, an etching process for removing a material film, a planarization process for planarizing a material film, and the like. The deposition process may include chemical vapor deposition (CVD), physical vapor deposition (PVD), atomic layer deposition (ALD), and the like, and the plating process may include electrolytic plating or electroless plating, and the like. The photolithography process may include photoresist coating, exposure, and development processes, and the like. The etching process may include dry etching or wet etching, and dry etching may include reactive ion etching (RIE), and the like. The planarization process may include etch-back, chemical mechanical polishing (CMP), and the like.

Referring to FIGS. 6 through 26 as a whole, the manufacturing method of the capacitor-less memory device 100b may include: forming a stacked structure ST1 of first semiconductor layers 140, first gate electrode layers 130, and first gate insulating layers 135 on the substrate 110; forming back gate electrode layers 170; forming first drain electrode layers 150; forming first source electrode layers 155 and second gate electrode layers 160; forming second semiconductor layers 180; forming a bit line 185; forming word lines 190; and forming control lines 195.

Hereinafter, each step will be described in more detail.

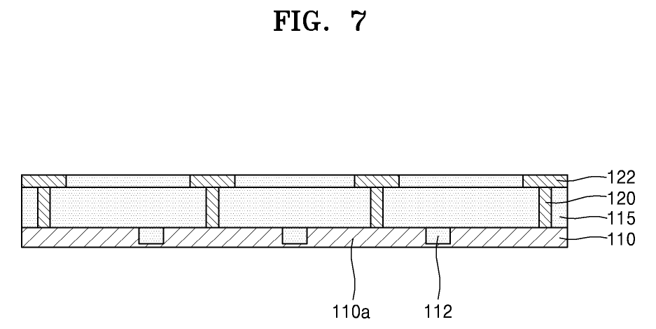

Referring to FIGS. 6 and 7, a substrate 110 may be provided. For example, the substrate 110 may include a semiconductor wafer or a silicon-on-insulator (SOI) substrate.

An interlayer insulating layer 115 may be formed on the substrate 110. Optionally, before forming the interlayer insulating layer 115, a device isolation layer 112 may be formed in the substrate 110 to define select lines 110a in the substrate 110. For example, the device isolation layer 112 may be formed by forming a shallow trench isolation (STI) in the substrate 110. The trench isolation layer may be formed by forming a trench (not shown) in the substrate 110 and then filling it with an insulating material. For example, the device isolation layer 112 may include a suitable insulating material such as silicon oxide, silicon nitride, a high-k dielectric material, or a combination thereof.

For example, the interlayer insulating layer 115 may be formed by depositing one or more layers of an insulating material such as silicon oxide on the substrate 110. For example, the interlayer insulating layer 115 may include a suitable insulating material such as silicon oxide, silicon nitride, a low-k dielectric material, or a combination thereof. A plurality of via electrodes 120 may be formed in the interlayer insulating layer 115 so as to extend vertically. For example, the via electrodes 120 may be formed by forming via holes (not shown) in the interlayer insulating layer 115 and then filling them with a conductive material. Contact pads 122 may be formed on the via electrodes 120. For example, the contact pads 122 may be formed by depositing a conductive material on the via electrodes 120 and then patterning the same. Optionally, after forming the contact pads 122, the interlayer insulating layer 115 may be additionally formed.

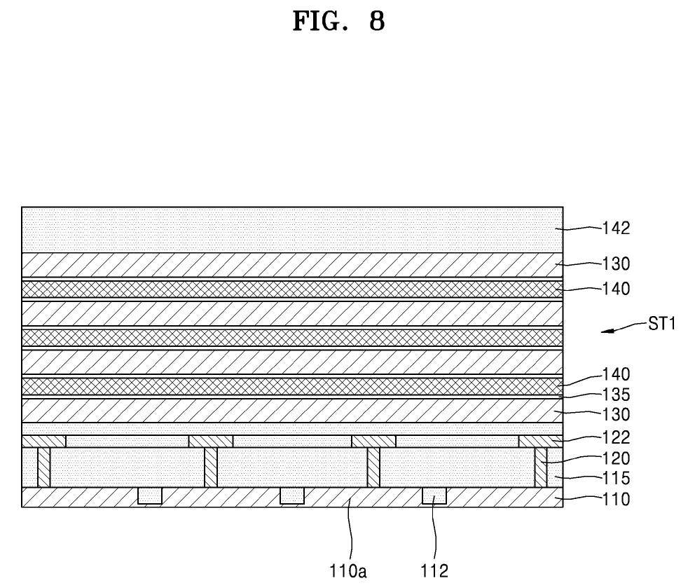

Referring to FIG. 8, a plurality of first gate electrode layers 130, a plurality of first semiconductor layers 140, and a plurality of first gate insulating layers 135 may be formed on the substrate 110. For example, the first semiconductor layers 140 stacked so as to be spaced apart from each other on the substrate 110, the first gate electrode layers 130 disposed between the first semiconductor layers 140, and the first gate insulating layers 135 disposed between the first semiconductor layers 140 and the first gate electrode layers 130 may be formed.

For example, the first gate electrode layers 130 may be formed of a conductive material such as a metal, doped polysilicon, a conductive oxide, or a conductive nitride. The first semiconductor layers 140 may be formed of a semiconductor material such as a Group IV semiconductor or an oxide semiconductor. The first gate insulating layers 135 may be formed of a suitable insulating material such as silicon oxide, silicon nitride, or a high-k dielectric.

For example, the first semiconductor layers 140 may be stacked on the substrate 110 so as to be spaced apart from each other, the first gate electrode layers 130 may be formed so as to be disposed on the first semiconductor layers 140, and the first gate insulating layers 135 may be formed so as to be disposed between the first semiconductor layers 140 and the first gate electrode layers 130.

In some embodiments, a first gate electrode layer 130 may be formed on the substrate 110, for example on the interlayer insulating layer 115, a first gate insulating layer 135 may be formed on the first gate electrode layer 130, a first semiconductor layer 140 may be formed on the first gate insulating layer 135, a first gate insulating layer 135 may be formed on the first semiconductor layer 140, and a first gate electrode layer 130 may be formed on the first gate insulating layer 135, and this may be repeated. Accordingly, a stacked structure ST1 may be formed in which the first gate electrode layers 130 are disposed above and below the first semiconductor layers 140 with the first gate insulating layers 135 interposed therebetween.

In some embodiments, it is also possible that the first semiconductor layer 140 is formed first on the interlayer insulating layer 115, followed by formation of the first gate insulating layer 135, and then formation of the first gate electrode layer 130, and this is repeated.

In some embodiments, a capping insulating layer 142 may be formed on the stacked structure ST1 of the plurality of first gate electrode layers 130, the plurality of first semiconductor layers 140, and the plurality of first gate insulating layers 135. For example, the capping insulating layer 142 may be formed of a suitable insulating material such as silicon oxide, silicon nitride, a high-k dielectric material, a low-k dielectric material, or a combination thereof.

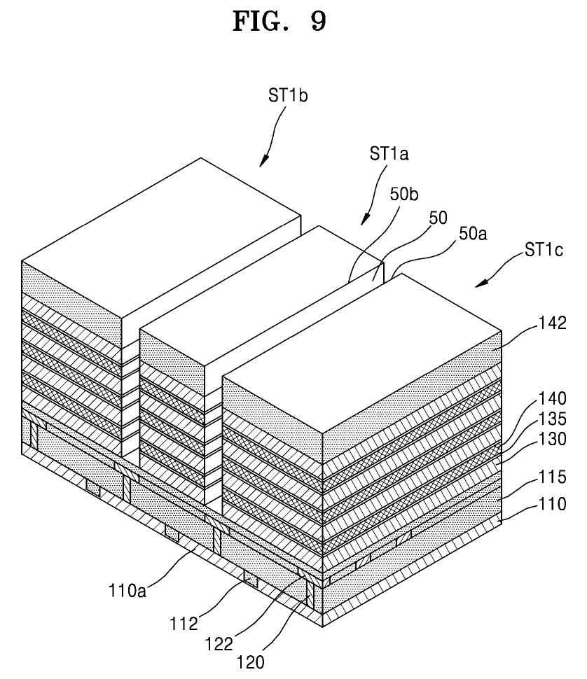

Referring to FIG. 9, the first gate electrode layers 130, the first semiconductor layers 140, and the first gate insulating layers 135 may be patterned to form at least one pair of first trenches 50. For example, the first trenches 50 may be formed using a photolithography process and an etching process.

In some embodiments, in the step of forming the first trenches 50, the capping insulating layer 142 may also be patterned together. Accordingly, the first trenches 50 may be formed by patterning the stacked structure of the capping insulating layer 142, the first gate electrode layers 130, the first semiconductor layers 140, and the first gate insulating layers 135.

By the first trenches 50, the stacked structure ST1 may be divided into a first stacked structure ST1a disposed between the first trenches 50, a second stacked structure ST1b disposed outside the first trenches 50, and a third stacked structure ST1c.

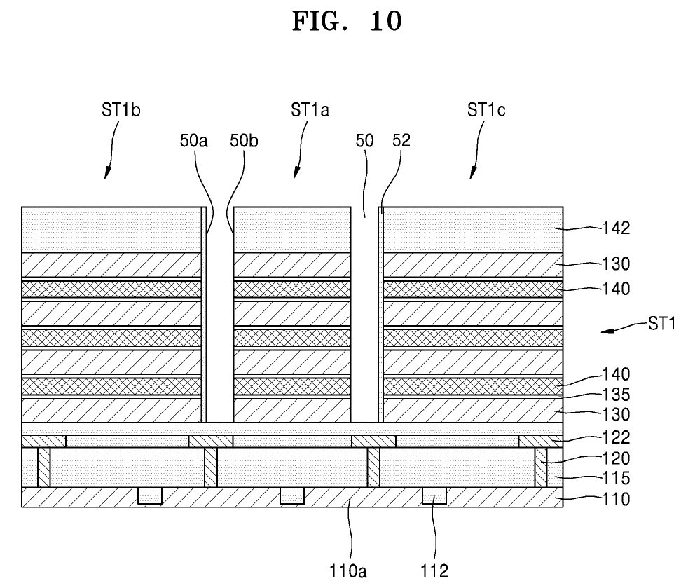

Referring to FIGS. 10 through 13, the first semiconductor layers 140 between the pair of first trenches 50 may be removed, and a plurality of back gate electrode layers 170 may be formed in the removed portions so as to be insulated from the first gate electrode layers 130. For example, the back gate electrode layers 170 may be formed of a suitable conductive material such as a metal, doped polysilicon, a conductive oxide, or a conductive nitride.

Referring to FIGS. 9 and 10, after the step of forming the first trenches 50, a first sidewall barrier layer 52 may be selectively formed on outer sidewalls 50a of the first trenches 50. The outer sidewalls 50a of the first trenches 50 refer to the sidewalls of the first trenches 50 in contact with the second stacked structure ST1b and the third stacked structure ST1c, and in contrast, the inner sidewalls 50b of the first trenches 50 may refer to the sidewalls of the first trenches 50 in contact with both sidewalls of the first stacked structure ST1a.

The first sidewall barrier layer 52 may serve to protect the first semiconductor layers 140 in the second and third stacked structures ST1b and ST1c outside the first trenches 50 when the first semiconductor layers 140 in the first stacked structure ST1a are subsequently removed. Accordingly, the first sidewall barrier layer 52 may be formed of a material having an etch selectivity with respect to the first semiconductor layers 140, for example, an insulating material.

For example, the step of forming the first sidewall barrier layer 52 may include: forming the first sidewall barrier layer 52 entirely on the inner surface of the capping insulating layer 142 and the first trenches 50; anisotropic etching to selectively remove the first sidewall barrier layer 52 on the bottom of the first trenches 50 and on the capping insulating layer 142; and selectively removing the first sidewall barrier layer 52 on the inner sidewalls 50b of the first trenches 50. By the anisotropic etching, the first sidewall barrier layer 52 may remain on the sidewalls of the trenches 50 in a spacer form, and thereafter, through a photolithography process and an etching process, the first sidewall barrier layer 52 may remain only on the outer sidewalls 50a of the first trenches 50.

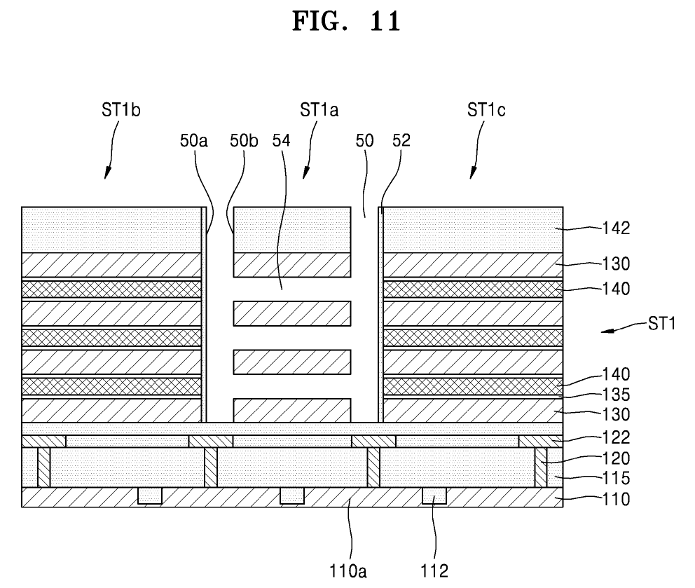

Referring to FIG. 11, while the first semiconductor layers 140 in the second stacked structure ST1b and the third stacked structure ST1c are protected by the first sidewall barrier layer 52, the first semiconductor layers 140 in the first stacked structure ST1a exposed by the first trenches 50 may be selectively etched. Accordingly, the first semiconductor layers 140 between the first trenches 50 may be selectively removed. For example, etching of the first semiconductor layers 140 may use isotropic etching, such as wet etching, to enable lateral etching.

By the etching described above, horizontal tunnels 54 communicating with the first trenches 50 may be formed in the portions where the first semiconductor layers 140 between the first trenches 50 have been removed.

Thereafter, the first sidewall barrier layer 52 may remain or may be removed.

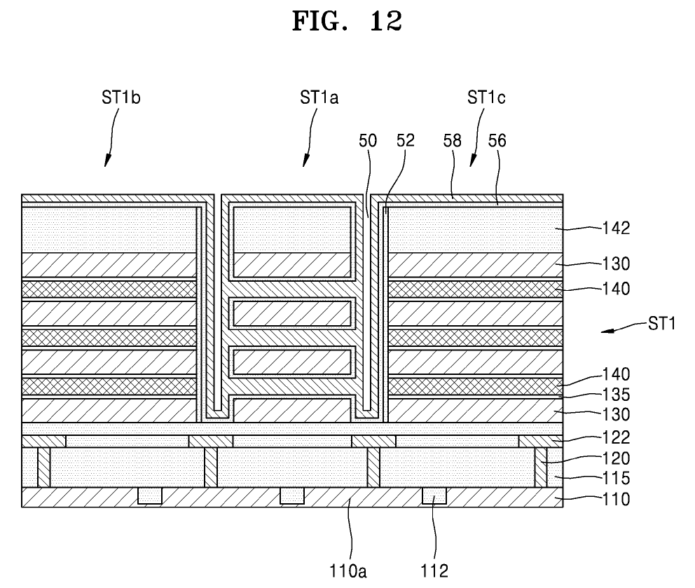

Referring to FIG. 12, a tunnel insulating layer 56 may be formed on the inner surface of the horizontal tunnels 54, and a conductive material 58 may be formed on the tunnel insulating layer 56 so as to fill the interior of the horizontal tunnels 54. When forming such conductive material 58, the interior of the first trenches 50 may not be filled. For example, the tunnel insulating layer 56 may include an insulating material such as silicon oxide, silicon nitride, or a high-k dielectric, and the conductive material 58 may be formed of a metal, doped polysilicon, a conductive oxide, or a conductive nitride. The tunnel insulating layer 56 and the conductive material 58 may be formed using chemical vapor deposition (CVD) or atomic layer deposition (ALD).

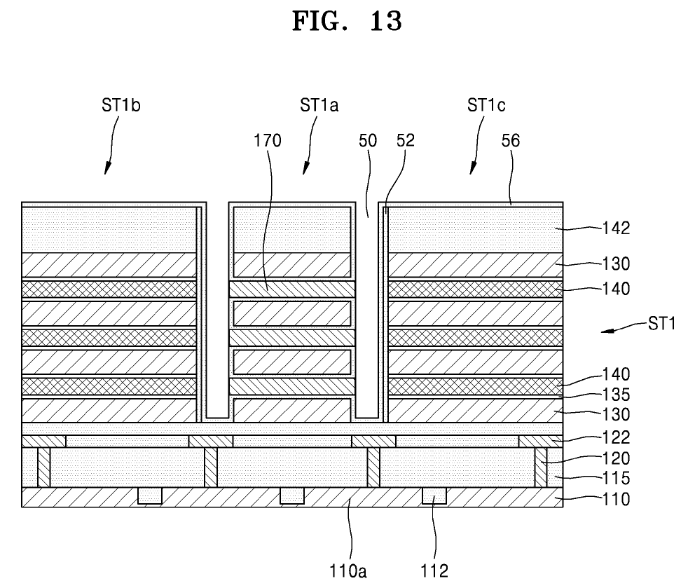

Referring to FIG. 13, the conductive material 58 remaining inside the first trenches 50, except for the interior of the horizontal tunnels 54, may be selectively removed. Accordingly, the conductive material 58 remains in the horizontal tunnels 54, and the back gate electrode layers 170 may be formed. In the first stacked structure ST1a, the tunnel insulating layer 56 is interposed between the back gate electrode layers 170 and the first gate electrode layers 130, so that they may be insulated from each other.

According to some embodiments, as described above, the step of forming the back gate electrode layers 170 may include: forming the horizontal tunnels 54 by removing the first semiconductor layers 140 between the first trenches 50 using the first sidewall barrier layer 52 as an etch protection layer; forming the tunnel insulating layer 56 on the inner surface of the horizontal tunnels 54; forming the conductive material 58 on the tunnel insulating layer 56 so as to fill the interior of the horizontal tunnels 54; and selectively removing the conductive material 58 remaining inside the first trenches 50 except for the interior of the horizontal tunnels 54.

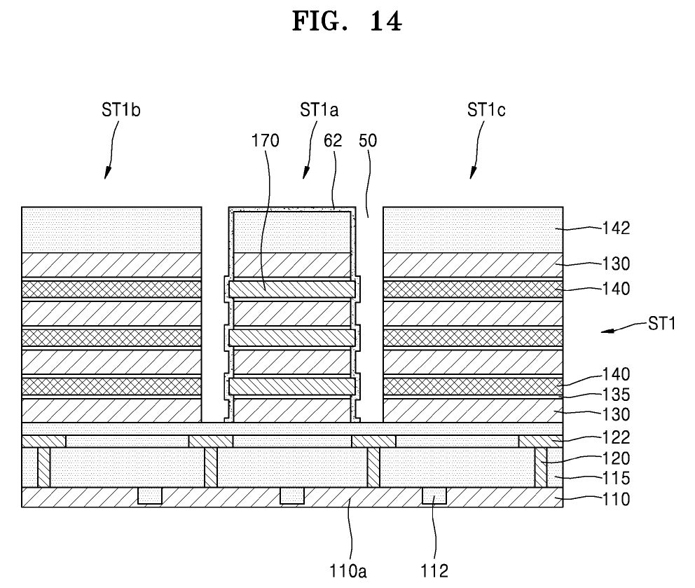

Referring to FIGS. 14 through 21, a plurality of first drain electrode layers 150 may be formed so as to be respectively connected to one side of the first semiconductor layers 140. For example, after removing one side of the first semiconductor layers 140 by a predetermined amount, a conductive material may be filled in the removed portions to form the plurality of first drain electrode layers 150 so as to be respectively connected to one side of the first semiconductor layers 140.

Subsequently, a plurality of first source electrode layers 155 and a plurality of second gate electrode layers 160 may be formed so as to be respectively connected to the other side of the first semiconductor layers 140. For example, after removing the other side of the first semiconductor layers 140 by a predetermined amount, a conductive material may be filled in the removed portions to form the plurality of first source electrode layers 155 and the plurality of second gate electrode layers 160 so as to be respectively connected to the other side of the first semiconductor layers 140.

Referring to FIG. 14, after forming the back gate electrode layers 170, the tunnel insulating layer 56 remaining inside and outside the first trenches 50 may be removed, and a second sidewall barrier layer 62 may be formed on the inner sidewalls 50b of the first trenches 50 exposing the sidewalls of the back gate electrode layers 170. The second sidewall barrier layer 62 may surround the first stacked structure ST1a and serve to protect the first stacked structure ST1a from etching in subsequent steps.

For example, the tunnel insulating layer 56 remaining inside and outside the first trenches 50 may be etched using isotropic etching such as wet etching. For example, the second sidewall barrier layer 62 may be formed entirely on the structure from which the tunnel insulating layer 56 has been removed, and then, through a photolithography and etching process, only the portion surrounding the first stacked structure ST1a may remain. For example, the second sidewall barrier layer 62 may include an insulating material such as silicon oxide, silicon nitride, or a high-k dielectric so as to have an etch selectivity when etching the first gate electrode layers 130 and the first semiconductor layers 140.

In some embodiments, in this etching step, the first sidewall barrier layer 52 may be removed simultaneously with or sequentially after the removal of the tunnel insulating layer 56.

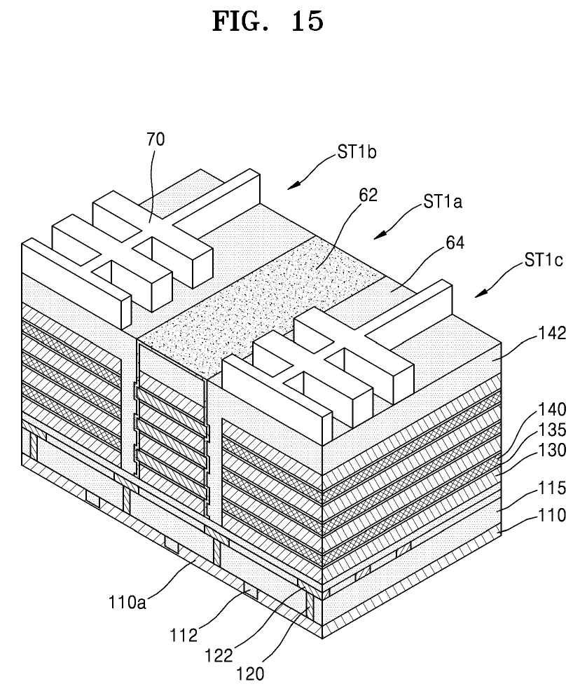

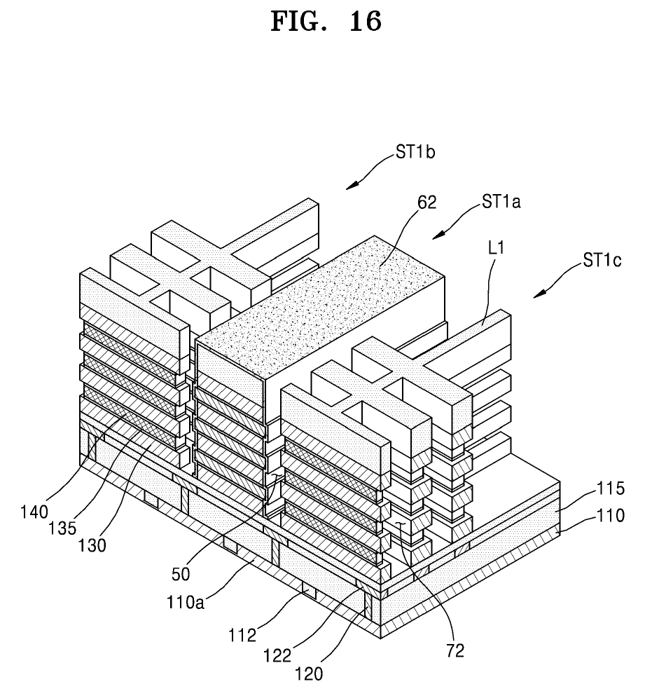

Referring to FIGS. 15 and 16, a buried insulating layer 64 may be formed to fill the first trenches 50. For example, the buried insulating layer 64 may include silicon oxide, silicon nitride, a high-k dielectric, or the like. Thereafter, the buried insulating layer 64 may be planarized using chemical mechanical polishing (CMP) or the like.

Subsequently, using the second sidewall barrier layer 62 as an etch protection layer, a plurality of second trenches 72 may be formed. For example, the second and third stacked structures ST1b and ST1c outside the first trenches 50 may be patterned by extending inward from both sides in a direction perpendicular to the first trenches 50 while leaving a central stacking line L1 parallel to the first trenches 50, thereby forming a plurality of second trenches 72 extending from the outside to the inside of the second and third stacked structures ST1b and ST1c by a predetermined distance in a direction perpendicular to the first trenches 50.

For example, the second trenches 72 may be formed using a photolithography and etching process. During the photolithography process, a hard mask layer 70 used as an etch protection layer may be formed on the second and third stacked structures ST1b and ST1c. For example, the hard mask layer 70 may include a single-layer or multi-layer insulating material. Thereafter, using the hard mask layer 70 and the second sidewall barrier layer 62 as etch protection layers, the exposed portions of the second and third stacked structures ST1b and ST1c may be selectively etched.

In some embodiments, when forming the second trenches 72, the first trenches 50 may be re-formed. For example, the hard mask layer 70 may be formed to expose the portions of the first trenches 50, and thereafter, during etching, the first trenches 50 may be formed together with the second trenches 72.

Subsequently, the first semiconductor layers 140 in the central stacking line L1 remaining between the second trenches 72 may be removed. For example, the first semiconductor layers 140 may be etched using isotropic etching such as wet etching. During such isotropic etching, the first semiconductor layers 140 in the second and third stacked structures ST1b and ST1c may also be partially etched. Therefore, such etching may be performed for a short time within the extent that the first semiconductor layers 140 in the central stacking line L1 are removed.

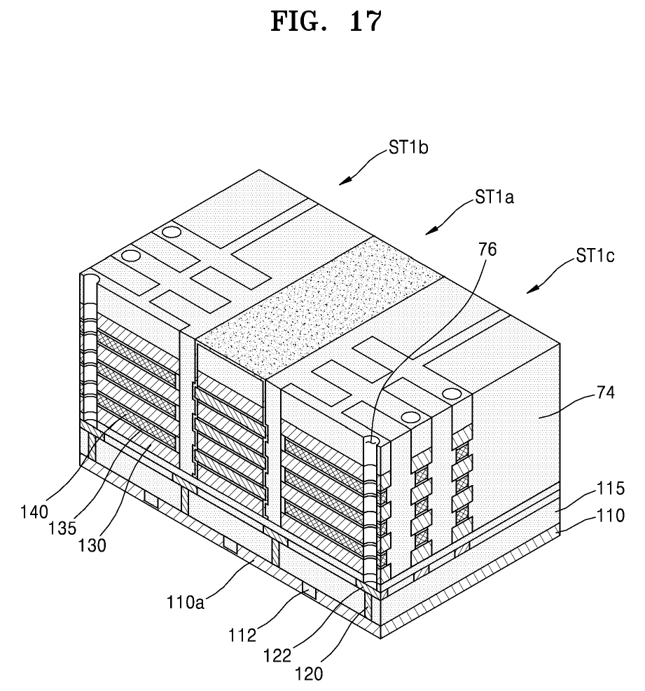

Referring to FIG. 17, a buried insulating layer 74 filling the first trenches 50 and the second trenches 72 may be formed. The buried insulating layer 74 may include a suitable insulating material such as silicon oxide, silicon nitride, silicon oxynitride, or a combination thereof.

Subsequently, first vertical holes 76 penetrating the buried insulating layer 74 and the first semiconductor layers 140 may be formed to expose one side of the first semiconductor layers 140. For example, the vertical holes 76 may be formed vertically from the outside of the second and third stacked structures ST1b and ST1c and may further be formed to a depth exposing the contact pads 122.

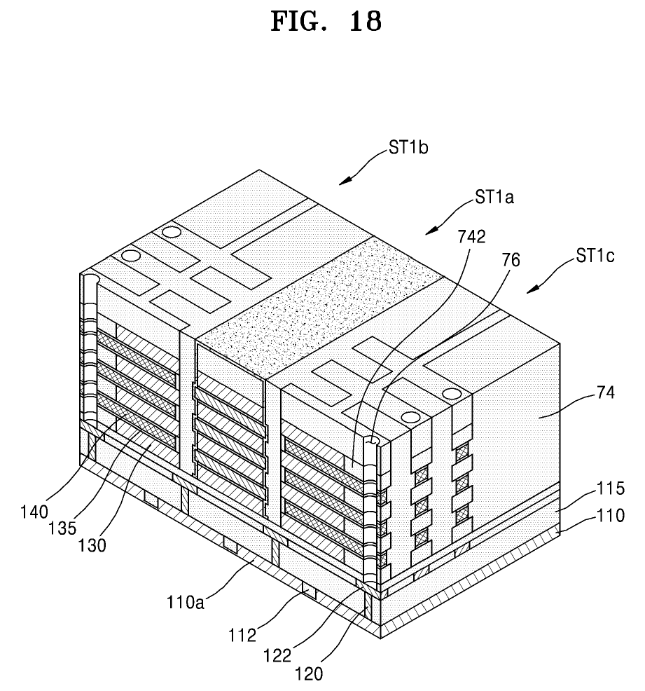

Referring to FIG. 18, one side of the first gate electrode layers 130 may be etched by a predetermined amount through the first vertical holes 76, and an insulating material 742 may be filled in the etched portions. Accordingly, one side of the first gate electrode layers 130 in the second and third stacked structures ST1b and ST1c may be recessed. However, in some embodiments, this recessing step of the first gate electrode layers 130 may be omitted.

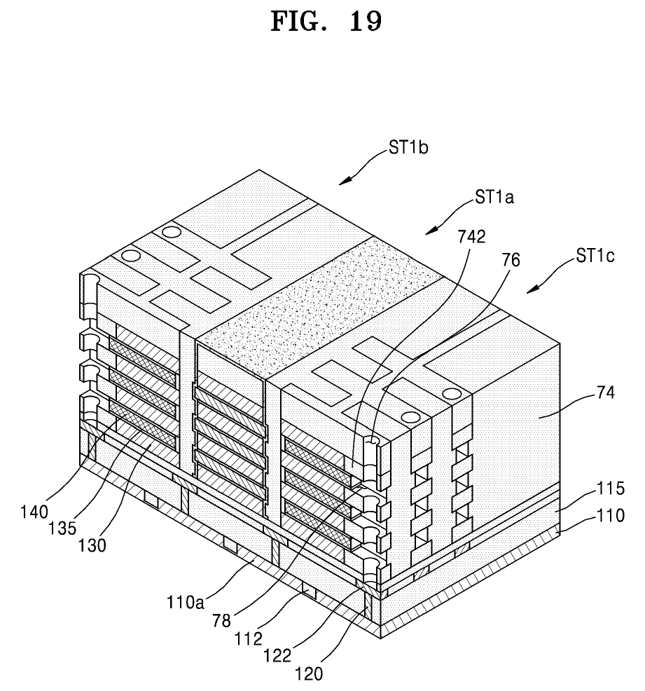

Referring to FIG. 19, one side of the first semiconductor layers 140 may be etched by a predetermined amount through the first vertical holes 76 to form first lateral recesses 78. For example, the first lateral recesses 78 may be formed by providing etchants for etching the first semiconductor layers 140 through the first vertical holes 76 using isotropic etching such as wet etching.

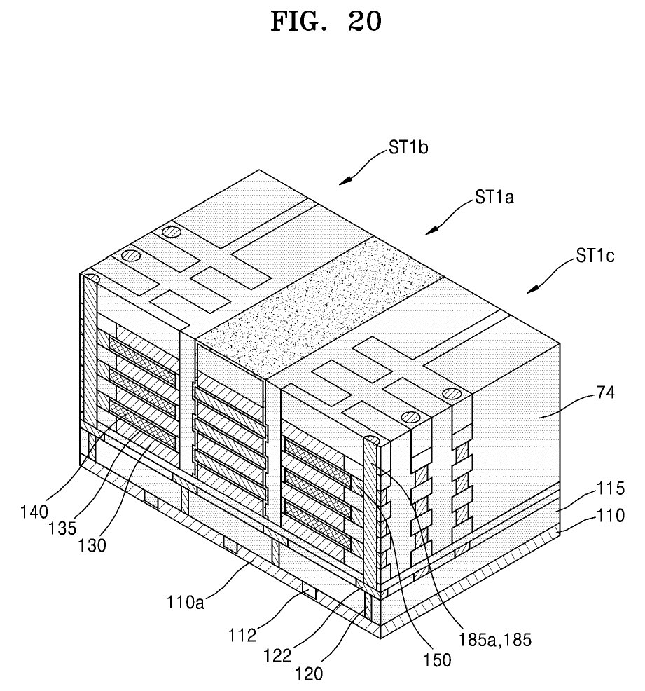

Referring to FIG. 20, a conductive material may be filled to fill the first lateral recesses 78 to form the first drain electrode layers 150 so as to be respectively connected to one side of the first semiconductor layers 140.

In some embodiments, as described above, the step of forming the first drain electrode layers 150 may include: forming the first vertical holes 76; etching one side of the first semiconductor layers 140 by a predetermined amount through the first vertical holes 76 to form the first lateral recesses 78; and filling a conductive material to fill the first lateral recesses 78.

In some embodiments, after forming the first drain electrode layers 150, a portion of the bit line 185 may be formed. For example, first vertical via electrodes 185a extending vertically so as to be connected to the first drain electrode layers 150 may be formed by filling the first vertical holes 76.

In some embodiments, the first drain electrode layers 150 and the first vertical via electrodes 185a may be simultaneously formed by filling a conductive material so as to simultaneously fill the first lateral recesses 78 and fill the first vertical holes 76.

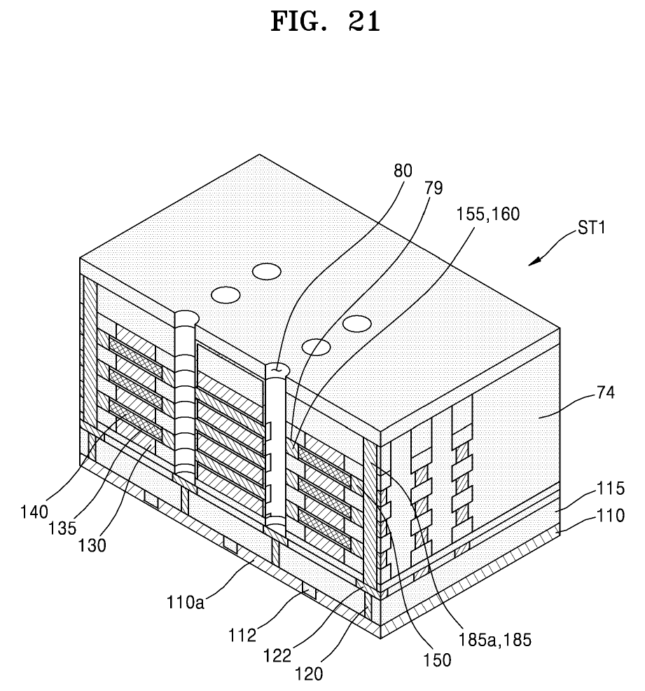

Referring to FIG. 21, a plurality of second vertical holes 80 penetrating the buried insulating layer 74 may be formed to expose the other side of the first semiconductor layers 140. For example, the second vertical holes 80 may be formed using a photolithography and etching process. The second vertical holes 80 may be formed to extend vertically at predetermined intervals in the space where the first trenches 50 were located, and may be formed, for example, to expose the contact pads 122.

Subsequently, the other side of the second semiconductor layers 140 may be etched by a predetermined amount through the second vertical holes 80 to form second lateral recesses 79, and a conductive material may be filled to fill the second lateral recesses 79 so as to be respectively connected to the other side of the first semiconductor layers 140, thereby simultaneously forming the first source electrode layers 155 and the second gate electrode layers 160. For example, the second lateral recesses 79 may be formed using isotropic etching similarly to the first lateral recesses 78. The first source electrode layers 155 and the second gate electrode layers 160 may be formed by depositing a conductive material using a deposition method such as chemical vapor deposition (CVD) or atomic layer deposition (ALD), and then selectively removing the portions exposed by the second vertical holes 80.

In some embodiments, as described above, the step of forming the first source electrode layers 155 and the second gate electrode layers 160 may include: forming the second vertical holes 80; etching the other side of the first semiconductor layers 140 by a predetermined amount to form the second lateral recesses 79; and filling a conductive material to fill the second lateral recesses 79.

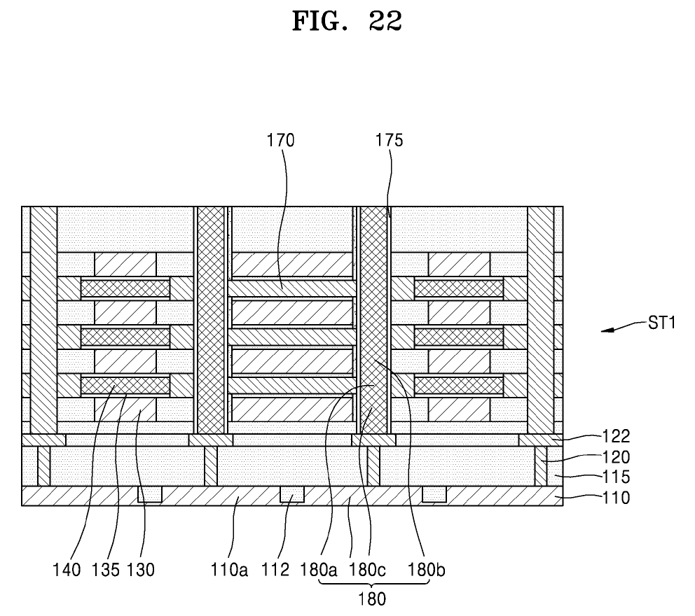

Referring to FIG. 22, second gate insulating layers 175 may be formed on the inner surface of the second vertical holes 80, and second semiconductor layers 180 may be formed on the second gate insulating layers 175.

For example, the second gate insulating layers 175 may be formed between the second gate electrode layers 160 and the second semiconductor layers 180, and between the back gate electrode layers 170 and the second semiconductor layers 180. The second gate insulating layers 175 may include a suitable insulating material such as silicon oxide, silicon nitride, or a high-k dielectric, and may be formed using chemical vapor deposition (CVD) or atomic layer deposition (ALD).

Subsequently, the second semiconductor layers 180 may be formed on the second gate insulating layers 175 so as to fill the second vertical holes 80. For example, the second semiconductor layers 180 may be formed to extend vertically between the second gate electrode layers 160 and the back gate electrode layers 170. The second semiconductor layers 180 may include a semiconductor material such as silicon, germanium, or an oxide semiconductor.

In some embodiments, in the second semiconductor layers 180, portions facing the second gate electrode layers 160 may function as channel layers 180a. The channel layers 180a may also be referred to as portions of the second semiconductor layers 180 between the second gate electrode layers 160 and the back gate electrode layers 170. Furthermore, portions of the second semiconductor layers 180 between the channel layers 180a may function as the second drain electrode layers 180b and the second source electrode layers 180c.

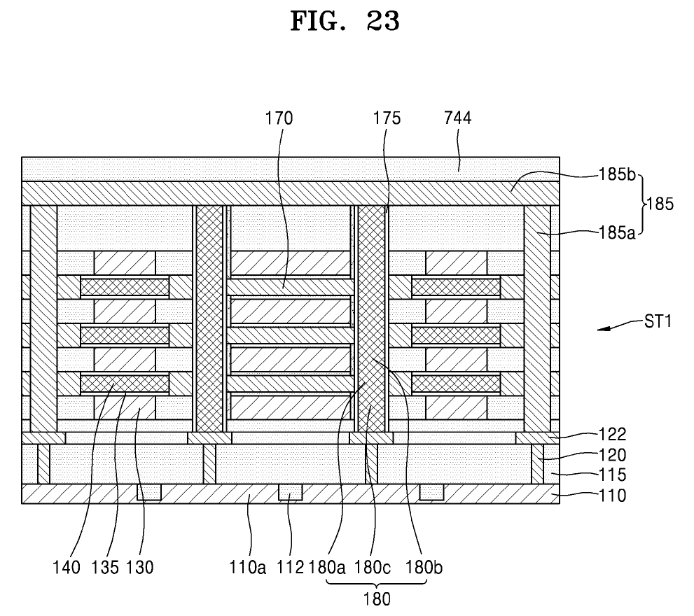

Referring to FIG. 23, first horizontal electrodes 185b may be formed as a portion of the bit line 185. For example, the first horizontal electrodes 185b may extend horizontally so as to be connected to the top ends of the second semiconductor layers 180, and may be connected to the first vertical via electrodes 185a.

In some embodiments, the step of forming the bit line 185 may be understood to include: forming the first vertical via electrodes 185a; and forming the first horizontal electrodes 185b.

Subsequently, an additional buried insulating layer 744 may be formed on the bit line 185.

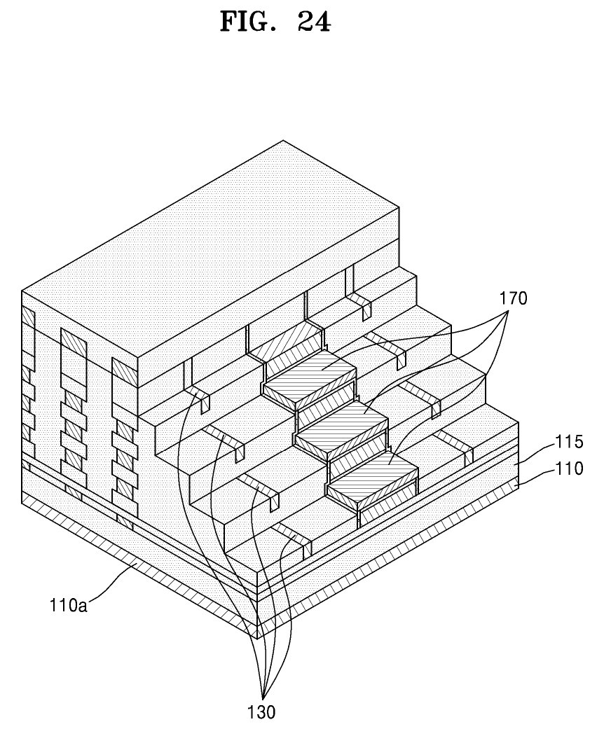

Referring to FIGS. 24 through 26, a plurality of word lines 190 may be formed so as to be respectively connected to the first gate electrode layers 130, and control lines 195 may be formed so as to be respectively connected to the back gate electrode layers 170.

Referring to FIG. 24, the resultant structure described above may be etched in a stepwise manner to form a staircase structure. For example, the end portions of the first gate electrode layers 130 may be etched in a stepwise manner to expose the first gate electrode layers 130 in a stepwise manner, and the end portions of the back gate electrode layers 170 may be etched in a stepwise manner to expose the back gate electrode layers 170 in a stepwise manner. Such a staircase structure may serve to expose the first gate electrode layers 130 and the back gate electrode layers 170 arranged in a stacked structure all at once from above. For example, such a staircase structure may be formed by repeatedly performing photolithography and etching processes.

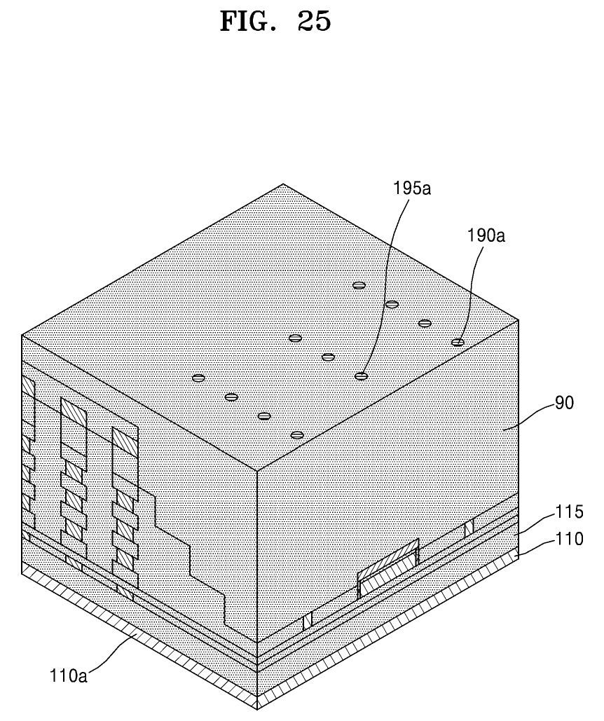

Referring to FIG. 25, second vertical via electrodes 190a may be formed on the stepwise exposed portions of the first gate electrode layers 130, and third vertical via electrodes 195a may be formed on the stepwise exposed portions of the back gate electrode layers 170.

For example, a capping insulating layer 90 may be formed on the staircase structure described above, and via holes extending to the stepwise exposed portions of the first gate electrode layers 130 and via holes extending to the stepwise exposed portions of the back gate electrode layers 170 may be formed through the capping insulating layer 90. Subsequently, these via holes may be filled with a conductive material to form the second vertical via electrodes 190a and the third vertical via electrodes 195a.

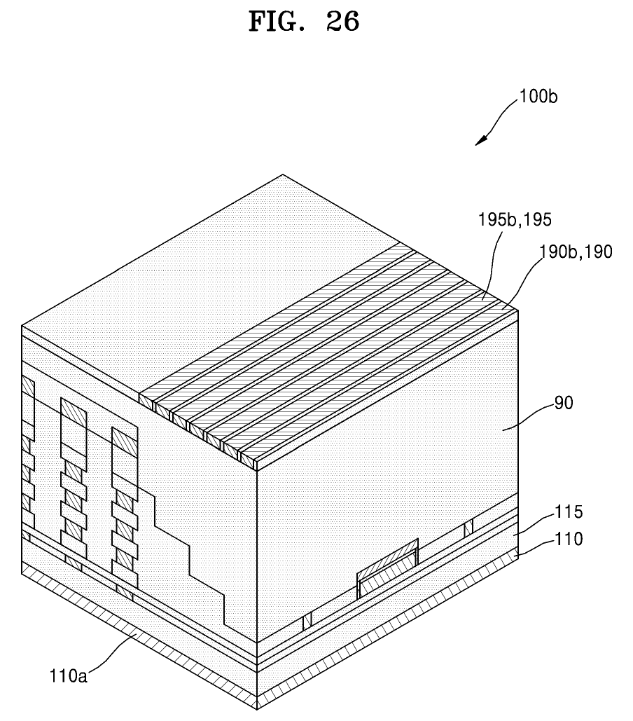

Referring to FIG. 26, second horizontal electrodes 190b respectively connected to the second vertical via electrodes 190a and extending in the horizontal direction may be formed, and third horizontal electrodes 195b respectively connected to the third vertical via electrodes 195a and extending in the horizontal direction may be formed. The horizontal direction of the second horizontal electrodes 190b and the third horizontal electrodes 195b refers to a direction horizontal to the substrate 110, and may be a direction perpendicular to the first trenches 50. The second vertical via electrodes 190a and the second horizontal electrodes 190b constitute the word line 190, and the third vertical via electrodes 195a and the third horizontal electrodes 195b may constitute the control line 195.

In some embodiments, the step of forming the word lines 190 may be understood to include: exposing the first gate electrode layers 130 in a stepwise manner; forming the second vertical via electrodes 190a; and forming the second horizontal electrodes 190b.

In some embodiments, the step of forming the control lines 195 may be understood to include: exposing the back gate electrode layers 170 in a stepwise manner; forming the third vertical via electrodes 195a; and forming the third horizontal electrodes 195b.

According to the manufacturing method described above, the capacitor-less memory device 100b having a three-dimensional structure may be formed with a highly integrated structure.

Although the present invention has been described with reference to the embodiments shown in the drawings, these are merely exemplary, and those skilled in the art will understand that various modifications and equivalent other embodiments are possible therefrom. Therefore, the true technical scope of protection of the present invention should be determined by the technical spirit of the appended claims.

What is claimed is:

1. A manufacturing method of a capacitor-less memory device, comprising:
forming a plurality of first semiconductor layers stacked on a substrate so as to be spaced apart from each other, a plurality of first gate electrode layers disposed between the plurality of first semiconductor layers, and a plurality of first gate insulating layers disposed between the plurality of first semiconductor layers and the plurality of first gate electrode layers;
patterning the plurality of first semiconductor layers, the plurality of first gate electrode layers, and the plurality of first gate insulating layers to form at least one pair of first trenches;
removing the first semiconductor layers between the pair of first trenches, and forming a plurality of back gate electrode layers in portions from which the first semiconductor layers have been removed, the plurality of back gate electrode layers being insulated from the plurality of first gate electrode layers;
forming a plurality of first drain electrode layers so as to be connected respectively to one side of the plurality of first semiconductor layers;
forming a plurality of first source electrode layers and a plurality of second gate electrode layers so as to be connected respectively to the other side of the plurality of first semiconductor layers;
forming a plurality of second semiconductor layers extending vertically between the plurality of second gate electrode layers and the plurality of back gate electrode layers;
forming a bit line connected to the plurality of first drain electrode layers and connected to an upper end of the plurality of second semiconductor layers;
forming a plurality of word lines so as to be connected respectively to the plurality of first gate electrode layers; and
forming a plurality of control lines so as to be connected respectively to the plurality of back gate electrode layers.

2. The manufacturing method of claim 1, further comprising: before forming the pair of first trenches, forming a capping insulating layer on a stacked structure of the plurality of first semiconductor layers, the plurality of first gate insulating layers, and the plurality of first gate electrode layers, wherein in the step of forming the pair of first trenches, the capping insulating layer is patterned together with the stacked structure.

3. The manufacturing method of claim 2, further comprising: after the step of forming the pair of first trenches, selectively forming a first sidewall barrier layer on outer sidewalls of the pair of first trenches, wherein the first sidewall barrier layer protects the first semiconductor layers outside the pair of first trenches when the first semiconductor layers between the pair of first trenches are removed.

4. The manufacturing method of claim 3, wherein the step of forming the first sidewall barrier layer comprises:
forming the first sidewall barrier layer entirely over the capping insulating layer and on inner surfaces of the first trenches;
performing anisotropic etching to selectively remove the first sidewall barrier layer on bottoms of the first trenches and on the capping insulating layer; and
selectively removing the first sidewall barrier layer on inner sidewalls of the pair of first trenches.

5. The manufacturing method of claim 3, wherein the step of forming the plurality of back gate electrode layers comprises:
using the first sidewall barrier layer as an etch protection layer, removing the first semiconductor layers between the pair of first trenches to form horizontal tunnels communicating with the pair of first trenches;
forming a tunnel insulating layer on inner surfaces of the horizontal tunnels;
forming a conductive material on the tunnel insulating layer so as to fill interiors of the horizontal tunnels; and
selectively removing the conductive material remaining inside the pair of first trenches, except for the conductive material inside the horizontal tunnels.

6. The manufacturing method of claim 5, further comprising: after forming the plurality of back gate electrode layers,
removing the tunnel insulating layer remaining inside and outside the pair of first trenches; and
forming a second sidewall barrier layer on inner sidewalls of the pair of first trenches that expose sidewalls of the plurality of back gate electrode layers.

7. The manufacturing method of claim 6, further comprising:
using the second sidewall barrier layer as an etch protection layer, patterning the stacked structure outside the pair of first trenches by extending inward from both sides in a direction perpendicular to the pair of first trenches while leaving a central stacked line parallel to the pair of first trenches, thereby forming a plurality of second trenches extending from an outer side to an inner side of the stacked structure by a predetermined distance in a direction perpendicular to the pair of first trenches;
removing the first semiconductor layers within the central stacked line remaining between the plurality of second trenches; and
forming a buried insulating layer filling the plurality of first trenches and the plurality of second trenches.

8. The manufacturing method of claim 7, wherein the step of forming the plurality of first drain electrode layers comprises:
forming a plurality of first vertical holes penetrating the buried insulating layer and the plurality of first semiconductor layers so as to expose one side of the plurality of first semiconductor layers;
etching one side of the plurality of first semiconductor layers by a predetermined amount through the plurality of first vertical holes to form first lateral recesses; and
filling a conductive material to fill the first lateral recesses so as to be connected respectively to one side of the plurality of first semiconductor layers.

9. The manufacturing method of claim 7, wherein the step of forming the plurality of first source electrode layers and the plurality of second gate electrode layers comprises:
forming a plurality of second vertical holes penetrating the buried insulating layer so as to expose the other side of the plurality of first semiconductor layers;
etching the other side of the plurality of first semiconductor layers by a predetermined amount through the plurality of second vertical holes to form second lateral recesses; and
filling a conductive material to fill the second lateral recesses so as to be connected respectively to the other side of the plurality of first semiconductor layers, thereby simultaneously forming the plurality of first source electrode layers and the plurality of second gate electrode layers.

10. The manufacturing method of claim 9, further comprising
forming a plurality of second gate insulating layers between the plurality of second gate electrode layers and the plurality of second semiconductor layers and between the plurality of back gate electrode layers and the plurality of second semiconductor layers, wherein the step of forming the plurality of second gate insulating layers and the step of forming the plurality of second semiconductor layers comprise:
forming the plurality of second gate insulating layers on inner surfaces of the plurality of second vertical holes; and
forming the plurality of second semiconductor layers on the plurality of second gate insulating layers to fill the plurality of second vertical holes.

11. The manufacturing method of claim 9, wherein the step of forming the bit line comprises:
forming a plurality of first vertical via electrodes extending vertically by filling the plurality of first vertical holes so as to be connected to the plurality of first drain electrode layers; and
forming a plurality of first horizontal electrodes extending horizontally so as to be connected to upper ends of the plurality of second semiconductor layers and connected to the plurality of first vertical via electrodes.

12. The manufacturing method of claim 11, wherein the plurality of first vertical via electrodes and the plurality of first drain electrode layers are formed simultaneously.

13. The manufacturing method of claim 1, wherein the step of forming the plurality of word lines comprises:
performing stepwise etching on end portions of the plurality of first gate electrode layers to expose the plurality of first gate electrode layers in a stepwise manner;
forming second vertical via electrodes on the stepwise exposed portions of the plurality of first gate electrode layers; and
forming second horizontal electrodes connected respectively to the second vertical via electrodes and extending in a horizontal direction.

14. The manufacturing method of claim 1, wherein the step of forming the plurality of control lines comprises:
performing stepwise etching on end portions of the plurality of back gate electrode layers to expose the plurality of back gate electrode layers in a stepwise manner;
forming third vertical via electrodes on the stepwise exposed portions of the plurality of back gate electrode layers; and
forming third horizontal electrodes connected respectively to the third vertical via electrodes and extending in a horizontal direction.

15. The manufacturing method of claim 1, further comprising: before the stacking of the plurality of first semiconductor layers,
forming an interlayer insulating layer on the substrate; and
forming a plurality of via electrodes extending vertically within the interlayer insulating layer, wherein the plurality of first semiconductor layers are stacked on the interlayer insulating layer.

16. The manufacturing method of claim 15, further comprising: before the step of forming the interlayer insulating layer,
forming a device isolation layer within the substrate to define select lines within the substrate, wherein the plurality of via electrodes are formed so as to be connected respectively to the select lines, and wherein the plurality of via electrodes connect the plurality of second semiconductor layers and a portion of the select lines and connect the plurality of bit lines and another portion of the select lines.

17. The manufacturing method of claim 1, wherein each of the plurality of first semiconductor layers has a planar shape, and the plurality of second semiconductor layers have a pillar shape.

18. The manufacturing method of claim 1, wherein the plurality of first semiconductor layers and the plurality of second semiconductor layers comprise an oxide semiconductor.

19. A manufacturing method of a capacitor-less memory device, comprising:
stacking a plurality of first semiconductor layers on a substrate so as to be spaced apart from each other;
forming a plurality of first gate electrode layers so as to be disposed between the plurality of first semiconductor layers;
forming a plurality of first gate insulating layers so as to be disposed between the plurality of first semiconductor layers and the plurality of first gate electrode layers;
patterning the plurality of first semiconductor layers, the plurality of first gate electrode layers, and the plurality of first gate insulating layers to form at least one pair of first trenches;
removing the first semiconductor layers between the pair of first trenches, and forming a plurality of back gate electrode layers in portions from which the first semiconductor layers have been removed, the plurality of back gate electrode layers being insulated from the plurality of first gate electrode layers;
removing one side of the plurality of first semiconductor layers by a predetermined amount, and then filling a conductive material in the removed portions so as to be connected respectively to one side of the plurality of first semiconductor layers, thereby forming a plurality of first drain electrode layers;
removing the other side of the plurality of first semiconductor layers by a predetermined amount, and then filling a conductive material in the removed portions so as to be connected respectively to the other side of the plurality of first semiconductor layers, thereby forming a plurality of first source electrode layers and a plurality of second gate electrode layers;
forming a plurality of second semiconductor layers extending vertically between the plurality of second gate electrode layers and the plurality of back gate electrode layers;
forming a plurality of second gate insulating layers between the plurality of second gate electrode layers and the plurality of second semiconductor layers and between the plurality of back gate electrode layers and the plurality of second semiconductor layers;
forming a bit line connected to the plurality of first drain electrode layers and connected to upper ends of the plurality of second semiconductor layers;
forming a plurality of word lines so as to be connected respectively to the plurality of first gate electrode layers; and
forming a plurality of control lines so as to be connected respectively to the plurality of back gate electrode layers.
